(19) United States
(12) Patent Application Publication
(10) Pub. No.: US 2025/0089305 A1
(43) Pub. Date: Mar. 13, 2025

(54) GATE-ALL-AROUND TRANSISTOR AND METHOD FOR MANUFACTURING THE SAME

(71) Applicant: INSTITUTE OF MICROELECTRONICS, CHINESE ACADEMY OF SCIENCES, Beijing (CN)

(72) Inventors: Yongliang Li, Beijing (CN); Huaizhi Luo, Beijing (CN); Jun Luo, Beijing (CN); Wenwu Wang, Beijing (CN)

(21) Appl. No.: 18/817,680

(22) Filed: Aug. 28, 2024

(30) Foreign Application Priority Data
Sep. 8, 2023 (CN) 202311161628.5

(51) Int. Cl. H01L 29/10; H01L 29/06; H01L 29/16; H01L 29/165; H01L 29/423; H01L 29/66; H01L 29/775; H01L 29/786

(52) U.S. Cl. CPC H10D 30/751; H10D 62/822; H10D 30/014; H10D 30/43; H10D 30/6735; H10D 30/6757; H10D 62/121; H10D 62/83

(57) ABSTRACT

A gate-all-around transistor and a method for manufacturing the same. The gate-all-around transistor comprises: a semiconductor substrate; a source, a drain, and at least one nanostructure layer, which are disposed on the semiconductor substrate; and a gate stack structure surrounding each nanostructure layer, where the at least one nanostructure layer is disposed between the source and the drain, each nanostructure layer comprises a first material layer and second material layers, the second material layers are disposed at two sides of the first material layer along a thickness direction of the first material layer, each of the first material layer and the second material layers is in contact with both the source and the drain, and at least a part of the second material layers is different from the first material layer in material.

The present application claims priority to Chinese Patent Application No. 202311161628.5, titled “GATE-ALL-AROUND TRANSISTOR AND METHOD FOR MANUFACTURING THE SAME”, filed on Sep. 8, 2023, with the China National Intellectual Property Administration, which is incorporated herein by reference in its entirety.

### FIELD

The present disclosure relates to the technical field of semiconductors, and in particular to a gate-all-around transistor and a method for manufacturing the gate-all-around transistor.

### BACKGROUND

Gate-all-around (GAA) transistors are advantageous in, for example, a higher capability of gate control, in comparison with planar transistors and fin field effect transistors. Hence, a semiconductor device may achieve better operating performances when all transistors in it are GAA transistors.

In conventional technology, only the silicon-channel GAA transistors having low carrier mobility is manufacturable through common techniques, and the operating performances of the GAA transistors need to be improved.

### SUMMARY

A gate-all-around (GAA) transistor and a method for manufacturing the GAA transistor are provided according to embodiments of the present disclosure. A material of a channel may be a semiconductor material other than silicon and have high carrier mobility, and hence the GAA transistor can have high operating performances.

In a first aspect, a GAA transistor is provided according to an embodiment of the present disclosure. The GAA transistor comprises: a semiconductor substrate; a source, a drain, and at least one nanostructure layer, which are disposed on the semiconductor substrate; and a gate stack structure surrounding each of the at least one nanostructure layer. The at least one nanostructure layer is disposed between the source and the drain. Each of the at least one nanostructure layer comprises a first material layer and second material layers, where the second material layers are disposed at two sides of the first material layer along a thickness direction of the first material layer. Each of the first material layer and the second material layers is in contact with both the source and the drain. At least a part of the second material layers is different from the first material layer in material.

In a second aspect, a method for manufacturing a GAA transistor is provided according to an embodiment of the present disclosure. The method comprises: forming a fin on a semiconductor substrate, where the fin comprises at least one sacrificial layer and at least one channel layer that are alternately stacked along a thickness direction of the semiconductor substrate, and both a topmost layer and a bottommost layer among the at least one sacrificial layer and the at least one channel layer belong to the at least one sacrificial layer; forming a mask layer astride the fin; etching the fin under masking of the mask layer; removing the at least one sacrificial layer remaining after the etching; thinning, along the thickness direction of the semiconductor substrate, the at least one channel layer remaining after the etching to form at least one first material layer, respectively; forming second material layers at two sides of each of the at least one first material layer along a thickness direction of said first material layer to obtain at least one nanostructure layer, where at least a part of the second material layers is different from said first material layer in material, and each nanostructure layer of the at least one nanostructure layer comprises a respective first material layer of the at least one first material layer and the second material layers at the two sides of the respective first material layer; filling one or more gaps with a dielectric layer, where each of the one or more gaps is located between adjacent ones of the at least one nanostructure layer, between and the semiconductor substrate and the at least one nanostructure layer, or between the at least one nanostructure layer and the mask layer; forming a source and a drain at two sides, respectively, of the fin remaining after the filling, along a length direction of the fin; removing at least a part of the mask layer and the dielectric layer; and forming a gate stack structure surrounding each nanostructure layer.

Herein the GAA transistor comprises the at least one nanostructure layer disposed between the source and the drain, and each nanostructure layer comprises the first material layer and the second material layers disposed at two sides of the first material layer along the thickness direction. At least the part of the second material layer is different from the first material layer in material. Channel materials of different types may provide different carrier mobilities and different conductivity. Since each nanostructure layer comprises the first material layer and the second material layers that are at least partially different in material, the part of the second material layer may be made of a semiconductor material higher in carrier mobility, that is, carrier mobility of the part of the second material layer may be higher than that of the first material layer. Moreover, the [100] crystal orientation is a main conductive orientation in the GAA transistor, and hence arranging the second material layers with higher carrier mobility at two sides of the first material layer along the thickness direction is capable to improve conductivity of each nanostructure layer. In addition, each of the first material layer and the second material layers is in contact with the source and the drain, and hence the source and the drain can be directly connected electrically via the first material layer(s) and the second material layers during operation of the GAA transistor. Thereby, the nanostructure layer has high carrier mobility and excellent conductivity throughout its length, which improves driving performances of the GAA transistor.

### BRIEF DESCRIPTION OF THE DRAWINGS

The drawings illustrated herein are intended for facilitating further understanding on the present disclosure and constitute a part of the present disclosure. Embodiments of the present disclosure are intended for explaining rather than limiting the present disclosure.

FIGS. 1 to 20 are schematic diagrams of intermediate structures during a process of manufacturing a gate-all-around (GAA) according to embodiments of the present disclosure.

### DETAILED DESCRIPTION OF EMBODIMENTS

Hereinafter embodiments of the present disclosure will be described with reference to the drawings. The description is only exemplary and is not intended for limiting the scope of the present disclosure. Herein description on well-known structures and techniques are omitted to avoid unnecessarily confusion on concepts of the present disclosure.

Various structural schematic diagrams for embodiments of the present disclosure are shown in the drawings. The drawings are not drawn to scale, and some details may be enlarged while some details may have been omitted for conciseness. Shapes, relative dimensions, and relative positions of various regions and layers shown in the figures are only exemplary. In practice, there may be deviations due to manufacturing tolerances or technical limitations. Those skilled in the art may design a region or a layer having a different shape, dimension, or position according to an actual requirement.

Herein when a layer/element is defined as being “on” another layer/element, it may be disposed directly on the other layer/element, or there may be intervening layers/elements between the two. In addition, in a case that one layer/element is “over/above” another layer/element in one orientation, such layer/element may be “under/beneath” the other layer/element in a reversed orientation. In order to clarify addressed technical issues, technical solutions, and beneficial effects of the present disclosure, the present disclosure will be further described in detail below with reference to the drawings and embodiments. Specific embodiments described herein are only intended for explaining the present disclosure rather than limiting the present disclosure.

In addition, terms such as “first” and “second” are for descriptive purposes and shall not be construed as indicating explicitly or implicitly relative importance among or a quantity of concerning technical features. That is, a subject modified by “first” or “second” may indicate one or more of such subjects. Unless explicitly indicated otherwise, herein the term “multiple” refers to two or more, and the term “some” refers to one or more.

Unless explicitly stated or limited otherwise, herein the terms “mounted”, “connected”, and “interconnected” shall be interpreted in a broad sense. For example, they may refer to fixed connection, detachable connection, or integral connection, may refer to mechanical connection or electrical connection, may refer to direct connection or indirect connection via an intermediate medium, and may refer to internal connection between two elements or interaction between two elements. Those skilled in the art may appreciate specific meaning of the above terms according to specific context.

Gate-all-around (GAA) transistors are advantageous in, for example, a higher capability of gate control, in comparison with planar transistors and fin field effect transistors. Hence, a semiconductor device may achieve better operating performances when all transistors in it are GAA transistors.

Generally, a material of a channel the conventional GAA transistor is grown along orientation [100], which facilitates transmission of electrons but not holes. The n-channel transistors utilize electrons to achieve conduction in the channel, while the p-channel transistors utilize holes to achieve conduction in the channel. Hence, the n-channel GAA transistors applying the [100] oriented channel may be subject to improvement in electron mobility and thus have good operating performances. In comparison, the p-channel GAA transistors applying the [100] oriented channel may not benefit from improvement in hole mobility and thus improvement in the operating performances is not satisfactory.

In the field, high-mobility materials such as germanium silicon, germanium, or the like, may be utilized to fabricate the channel in the p-channel GAA transistors to improve the hole mobility. In current practice, high selectivity is only achieved in etching a sacrificial layer made of a high-mobility material, such as germanium silicon, germanium, or the like, with respect to etching a channel layer made of silicon, and it is difficult achieve high selectivity in etching a sacrificial layer made of silicon with respect to etching a channel layer made of the high-mobility material. As an example, the high selectivity refers to higher than or equal to 100:1. Hence, it is difficult to manufacture a p-channel GAA transistor utilizing the high-mobility material as it channel, which hinders improving the operating performances of the GAA transistors.

A GAA transistor and a method for manufacturing the GAA transistor are provided according to embodiments of the present disclosure. In the GAA transistor, at least one nanostructure layer is disposed between a source and a drain, and each nanostructure layer comprises a first material layer and second material layers disposed at two sides of the first material layer along a thickness direction of the first material layer. At least a part of the second material layer is different from the first material layer in material. Each of the first material layer and the second material layers is in contact with the source and the drain. Thereby, driving performances of the GAA transistor are improved.

In a first aspect, a GAA transistor is provided according to an embodiment of the present disclosure. The GAA transistor may be an n-channel transistor or a p-channel transistor. Reference is made to FIG. 20. The GAA transistor comprises a semiconductor substrate 11, a source 28, a drain 29, at least one nanostructure layer 25, and a gate stack structure 31. The source 28, the drain 29, and the at least one nanostructure 25 are disposed on the semiconductor substrate 11. The gate stack structure 31 surrounds each nanostructure layer 25. The at least one nanostructure layer 25 is disposed between the source 28 and the drain 29. Reference is made to FIG. 16 and FIG. 20. Each nanostructure layer 25 comprises a first material layer 20 and second material layers 21, and the second material layers 21 are disposed at two sides of the first material layer 20 along a thickness direction of the first material layer 20. The first material layer 20 and each second material layer 21 are both in contact with the source 28 and the drain 29. At least a part of the second material layer 21 is different from the first material layer 20 in material.

In an embodiment, the semiconductor substrate refers to a substrate on which no structure has been formed. For example, the semiconductor substrate may be a silicon substrate, a germanium silicon substrate, a germanium substrate, or a silicon-on-insulator substrate.

In another embodiment, the semiconductor substrate refers to a substrate on which one or more structures have been formed. A structure that has been formed on the semiconductor substrate may depend on an actual application and is not specifically limited herein. As an example, the semiconductor substrate may comprise a semiconductor base and a GAA transistor that has been formed on the semiconductor base through a conventional method. A GAA transistor to be formed according to a method provided herein and the GAA transistor formed through the conventional method are located on the semiconductor base and spaced apart from each other along a direction parallel to a surface of the semiconductor base. As another example, a semiconductor device to be formed according to a method provided herein serves as a component in a second bottommost layer or an even higher layer in an integrated circuit. In such case, the semiconductor substrate may comprise a semiconductor base, at least one layer of semiconductor devices located beneath such semiconductor device, and an interlayer dielectric layer that isolates semiconductor devices belonging to different layers.

Materials of the source and the drain may be a semiconductor material, such as silicon, germanium silicon, germanium, or the like. The source and the drain may be identical or different in material. Specific materials of the source and the drain may depend on a conductivity type of the GAA transistor. As an example, the GAA transistor is a p-channel transistor. In such case, the materials of the source and the drain may comprise germanium, germanium silicon that is high in germanium content, or another semiconductor material, and thereby a compressive stress is provide in each nanostructure layer to improve driving performances of the GAA transistor. As another example, the GAA transistor is an n-channel transistor. In such case, the materials of the source and the drain may comprise silicon, germanium silicon that is low in germanium content, or another semiconductor material, and thereby a tensile stress is provide in each nanostructure layer to improve driving performances of the GAA transistor.

A quantity of the at least one nanostructure layer may be only one, or there may be multiple nanostructure layers that are spaced apart along a thickness direction of the semiconductor substrate and located between the source and the drain. A specific quantity of the nanostructure layers may depend on an actual situation, as long as it is appropriate in the GAA transistor provided herein.

Reference is further made to FIG. 20. The second material layer 21 may be disposed right at the two sides of the corresponding first material layer 20 in each nanostructure layer 25. Alternatively, the second material layer may be not only disposed right at the two sides of the corresponding first material layer 20, but also extend into a region out of the first material layer 20 along a length direction of the first material layer. The length direction is parallel to a length direction of the gate stack structure.

Specific materials of the first material layer and the second material layers may depend on a conductivity type of the GAA transistor and an actual application, and hence are not specifically limited herein.

As an example, the GAA transistor is an n-channel transistor. The first material layer may be made of silicon, and at least the part of the second material layer may be made of another semiconductor material, e.g., germanium silicon that is low in germanium content.

Thereby, the carrier mobility in the nanostructure can be improved in the n-channel GAA transistor. In an embodiment, the germanium content in such germanium silicon may be greater than or equal to 0 and less than 10%.

As another example, the GAA transistor is a p-channel transistor. The first material layer may be made of silicon, and at least the part of the second material layer may be made of another semiconductor material, e.g., germanium silicon that is high in germanium content. Thereby, the carrier mobility in the nanostructure can be improved in the p-channel GAA transistor. In an embodiment, the germanium content in such germanium silicon may be greater than or equal to 10% and less than 60%. The germanium content in such range can prevent that the germanium silicon in the second material layer has such little germanium that there is only poor improvement in driving performances of the p-channel GAA transistor. Moreover, it can prevent that the germanium silicon has such much germanium that the second material layers are subject to dense defects due to a large lattice mismatch between the first material layer and the second material layers. Hence, high crystal quality can be achieved throughout the nanostructure, which improves a yield of the GAA transistors.

In a case that the first material layer is made of silicon, manufacture of the GAA transistor provided herein is compatible with common techniques for manufacturing the conventional GAA transistors. Thereby, the GAA transistors provided herein can be manufactured with little difficulty.

A material of the second material layer may stay the same along a thickness direction may include the same the materials. For example, the material of the second material layer is only germanium silicon, only silicon, or the like, throughout its thickness. Alternatively, reference is made to FIG. 16 and FIG. 20, where each second material layer 21 may comprise a first semiconductor layer 22 and a second semiconductor layer 23 that are different in material. The first semiconductor layer 22 is disposed on the corresponding first material layer 20, and the second semiconductor layer 23 is disposed on the first semiconductor layer 22. A material of the second semiconductor layer 23 may be silicon. In such case, the first semiconductor layer 22 is configured to improve the carrier mobility of each nanostructure layer 25, and the second semiconductor layer 23 (i.e., silicon) on the first semiconductor layer 22 is capable to improve manufacturing compatibility of the GAA transistor with common techniques. Hence, the GAA transistor can manufactured with less difficulty.

In an embodiment, types of a material of the above first semiconductor layer may refer to the aforementioned types of the material of the part of the second material layer, and details would not be repeated herein.

Thicknesses of the first material layer and the second material layer may depend on an actual application and is not specifically limited herein.

In an embodiment, the thickness of the first material layer may be greater than or equal to 1 nm and less than or equal to 5 nm. For example, the thickness of the first material layer may be 1 nm, 2 nm, 3 nm, 4 nm, 5 nm, or the like. The above thickness range is capable to prevent that the thickness of the first material layer is such small that the first material layer is likely to bend or break due to low structural strength during the actual manufacturing process. Hence, a yield of the GAA transistors can be improved. In actual manufacture, the channel layer(s) for fabricating the first material layer(s) are thinned along the thickness direction of the semiconductor substrate to provide a space to be filled by the second material layers. Thereby, the above thickness range can further prevent that the space is such thin due to a large thickness of the first material layer that the second material layer is too thin. That is, a degree of improving the driving performances of the GAA transistor due to the second material layers can be ensured.

In an embodiment, the thickness of the second semiconductor layer may be greater than or equal to 0.3 nm and less than or equal to 1.5 nm. For example, the thickness of the second semiconductor layer may be 0.3 nm, 0.5 nm, 0.8 nm, 1 nm, 1.2 nm, 1.5 nm, or the like. The above thickness range is capable to prevent that the second semiconductor layer is too thin to improve the compatibility of manufacture of the GAA transistors with the common techniques. Thereby, a high yield of the GAA transistors is ensured. Moreover, in a case that a total thickness of each nanostructure layer is fixed, the above thickness range is further capable to prevent the first semiconductor layer from being too thin due to thick second semiconductor layers. Thereby, a degree of improving driving performances of the GAA transistor through the second semiconductor layer is ensured.

A total thickness of the second material layers may depend on a height of the space formed through thinning the channel layer(s), which are configured to fabricate the first material layer(s), along the thickness direction of the semiconductor substrate. In an embodiment, the total thickness of the second material layers is less than or equal to the height of such space. Hence, the gate stack structure can be normally formed, and a yield of the GAA transistor can be improved.

The gate stack structure may comprise a gate dielectric layer, which surrounds each nanostructure layer, and a gate located on the gate dielectric layer. A material of the gate dielectric layer may comprise a dielectric material, such as HfO₂, ZrO₂, TiO₂, Al₂O₃, or the like. A material of the gate may comprise a conductive material, such as TiN, TaN, TiSiN, or the like.

Reference is further made to FIG. 20. In an embodiment, the GAA transistor may further comprise a gate sidewall 18, which is disposed at least at two sides of the gate stack structure 31 along a length direction (which points from the source to the drain, or vice versa) of the gate stack structure 31. The gate wall 18 is configured to suppress current leakage. The gate sidewalls 18 are astride edge portions, which correspond to two edges along the length direction, of the at least one nanostructure layer 25. A material of the gate sidewall 18 may comprise an insulating material, such as silicon oxide, silicon nitride, or the like, and a thickness of the gate sidewall 18 may depend on an actual application, which is not specifically limited herein.

Reference is further made to FIG. 20. In a case that the GAA transistor comprises the gate sidewalls 18, a portion of each nanostructure layer 25 located right below the gate sidewalls 18 is identical to another portion of such nanostructure layer 25 surrounded by the gate stack structure 31 in structure and material.

Reference is further made to FIG. 20. The GAA transistor further comprises one or more inner sidewalls 27. Each inner sidewall 27 is disposed between the gate stack structure 31 and the source 28 and/or between the gate stack structure 31 and the drain 29. The inner sidewall(s) 27 is capable to a length of the formed gate stack structure 31 and reduce parasitic capacitance between the gate stack structure 31 and one or both of the source 28 and the drain 29. Thereby, electrical performances of the GAA transistor can be improved. In an embodiment, a material of the inner sidewall 27 may comprise an insulating material, such as silicon nitride, silicon oxynitride, or the like.

Reference is further made to FIG. 20. The GAA transistor comprises the at least one nanostructure layer 25 disposed between the source 28 and the drain 29, and each nanostructure layer 25 comprises the first material layer 20 and the second material layers 21 disposed at two sides of the first material layer 20 along the thickness direction. At least the part of the second material layer 21 is different from the first material layer 20 in material. Channel materials of different types may provide different carrier mobilities and different conductivity. Since each nanostructure layer 25 comprises the first material layer 20 and the second material layers 21 that are at least partially different in material, the part of the second material layer 21 may be made of a semiconductor material higher in carrier mobility, that is, carrier mobility of the part of the second material layer 21 may be higher than that of the first material layer 20. Moreover, the [100] crystal orientation is a main conductive orientation in the GAA transistor, and hence arranging the second material layers 21 with higher carrier mobility at two sides of the first material layer 20 along the thickness direction is capable to improve conductivity of each nanostructure layer 25. In addition, each of the first material layer 20 and the second material layers 21 is in contact with the source 28 and the drain 29, and hence the source 28 and the drain 29 can be directly connected electrically via the first material layer(s) 20 and the second material layers 21 during operation of the GAA transistor. Thereby, the nanostructure layer has high carrier mobility and excellent conductivity throughout its length, which improves driving performances of the GAA transistor.

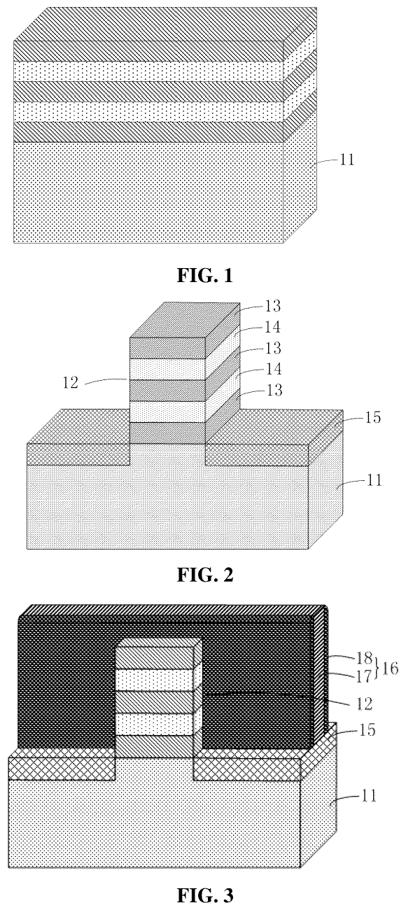

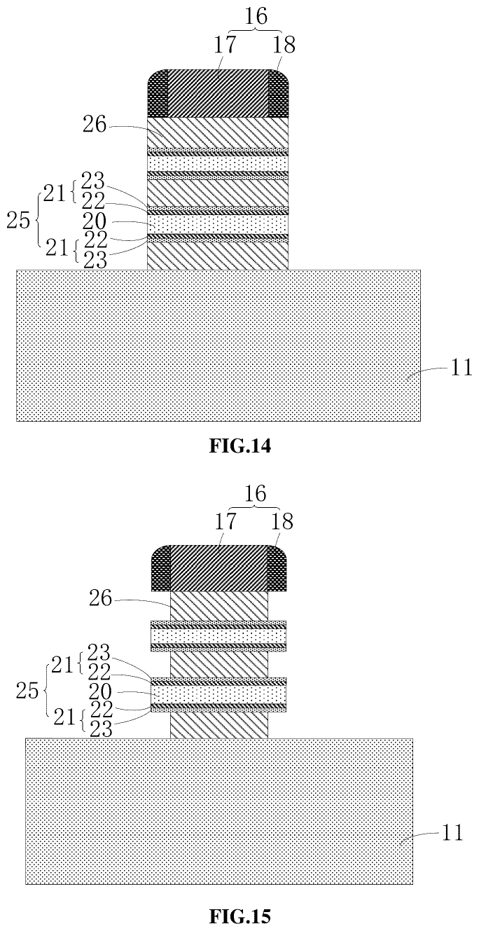

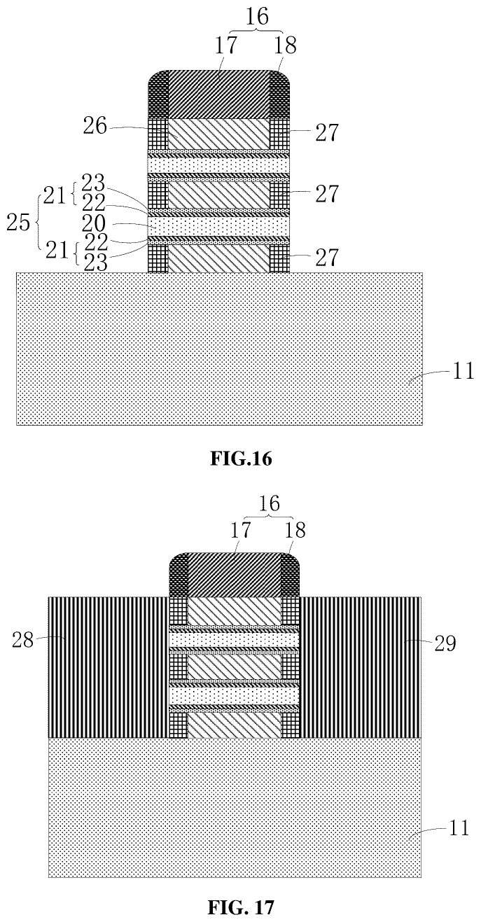

In a second aspect, a method for manufacturing a GAA transistor is provided according to an embodiment of the present disclosure. Hereinafter a process of the manufacturing is described in conjunction with stereoscopic or cross-sectional views of intermediate structures as shown in FIGS. 1 to 20. In an embodiment, the method comprises following steps.

Reference first made to FIG. 2. A fin 12 is formed on a semiconductor substrate 11. The fin 12 comprises at least one sacrificial layer 13 and at least one channel layer 14 that are alternately stacked along a thickness direction of the semiconductor substrate 11. Among alternately stacked layers, the topmost layer and the bottommost layer both are sacrificial layers 13.

In an embodiment, each channel layer in the fin is configured to fabricate a corresponding first material layer in the GAA transistor. Hence, a material of each channel layer may depend on the material of the corresponding first material layer as illustrated in the foregoing description. In addition, a quantity of the channel layer(s) in the fin may be equal to a quantity of nanostructure(s) in the GAA transistor. A thickness of each channel layer may depend on a structure to be fabricated on the semiconductor substrate. Generally, a semiconductor devices comprises a large number of transistors to implement corresponding functions. Hence, a thickness of each channel layer may depend on a maximum thickness of a portion, which is identical to the channel layer in thickness, of the corresponding nanostructure layers among different GAA transistors to be fabricated on the semiconductor substrate. Thereby, different nanostructure layers in different GAA transistors are capable to be fabricated from the same channel material layer. Efficiency of manufacturing semiconductor devices is improved, while costs of manufacturing semiconductor devices are reduced.

As an example, a first GAA transistor is to be formed on a partial region of the semiconductor substrate using through the method provided herein, and a second GAA transistor is to be formed on another region of the semiconductor substrate through a conventional method. It is assumed that the first material layer in the first GAA transistor is identical to a nanostructure layer in the second GAA transistor, and a thickness of each nanostructure layer in the second GAA transistor is greater than a thickness of the corresponding first material layer in the first GAA transistor. In such case, a thickness of each channel layer is equal to the thickness of the corresponding nanostructure layers in the second GAA transistor. Thereby, compatibility between the method provided herein and a process of manufacturing the conventional GAA transistor can be improved, and the manufacture is less difficult.

A material of the sacrificial layer(s) may be any semiconductor material different from the material of the channel layer(s). A specific material of the sacrificial layer(s) may depend on a conductivity type of the to-be-manufactured GAA transistor, the material of the channel layer(s), and an actual requirement. As an example, the GAA transistor is a p-channel transistor. In such case, the material of the channel layer(s) may be silicon, the material of the sacrificial layer(s) may be germanium silicon, and germanium content of the germanium silicon may depend on an actual requirement while ensuring high etching selectivity of the sacrificial layer(s) with respect to and the channel layer(s).

After each sacrificial layer that remains in a subsequent step is removed, a gate stack structure of the GAA transistor would be formed to fill gaps that are between adjacent nanostructure layers and between the bottommost nanostructure layer and the semiconductor substrate. Hence, a thickness of each sacrificial layer may depend on a thickness of the gate stack structure.

Reference is made to FIG. 1. In practice, material layers for forming the alternately stacked sacrificial layer(s) and the channel layer(s) are grown through epitaxy or formed through another technique. Then, the material layers, maybe along with a part of the semiconductor substrate 11, are patterned through, for example, photolithography and etching, to form a fin structure on the semiconductor substrate 11. Reference is further made to FIG. 2. Afterwards, shallow trench isolation 15 may be formed on the semiconductor substrate 11 through, for example, deposition and etching. A top surface of the shallow trench isolation 15 is lower than a bottom surface of the bottommost sacrificial layer 13 in the fin structure. Herein the fin 12 may refer to a portion of the fin structure 15 exposed outside of the shallow trench isolation 15.

Reference is made to FIG. 3. Then, a mask layer 16 astride a portion of the fin 12 is formed. Reference is made to FIG. 4. The fin is etched under masking of the mask layer 16.

In practice, a mask material may be formed through, for example, deposition, to cover the structure that has been formed. Then, the mask material is planarized through, for example, chemical mechanical polishing. Afterwards, the mask material is patterned through at least photolithography or the like to fabricate the mask layer astride only the portion of the fin. A specific material of the mask layer may depend on an actual application. For example, the material of the mask layer may be photoresist, silicon nitride, silicon oxide, silicon oxynitride, aluminum oxide, or titanium oxide. Reference is further made to FIG. 4. The fin 12 is then removed through, for example, dry etching or wet etching under masking of the mask layer 16. After the removal, two side surfaces along a length direction (i.e., a direction pointing from the to-be-formed source to the to-be-formed drain, or vice versa), of each channel layer 14 and each sacrificial layer 13 that remain, are exposed.

Reference is further made to FIG. 3. In some embodiments, a gate replacement technique is adopted during manufacture of the GAA transistor. In such case, the mask layer 16 may comprise a sacrificial gate 17 and a gate sidewall 18, and the gate sidewall 18 is located at least at two sides of the sacrificial gate 17 along the length direction. A material of the above sacrificial gate 17 may be polysilicon or the like, and a material of the gate sidewall 18 may refer to the foregoing description.

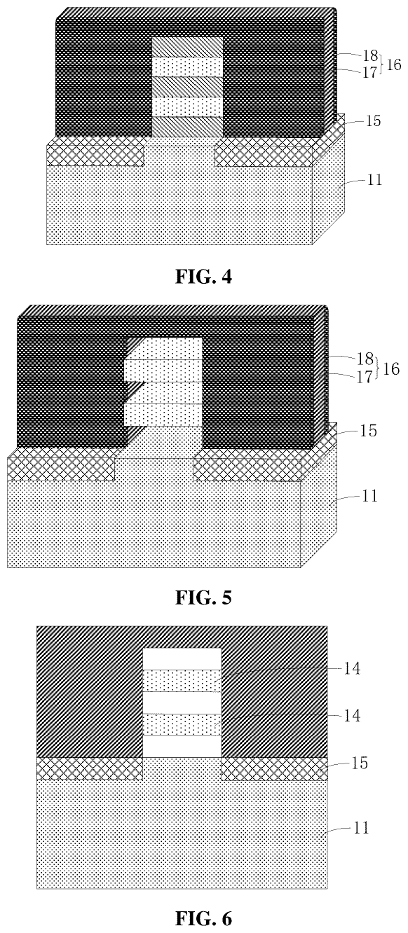

Reference is made to FIG. 5 and FIG. 6. Each remaining sacrificial layer may be removed through, for example, dry etching or wet etching. After the removal, the two side surfaces of each remaining channel layer 14 along the length direction are still exposed.

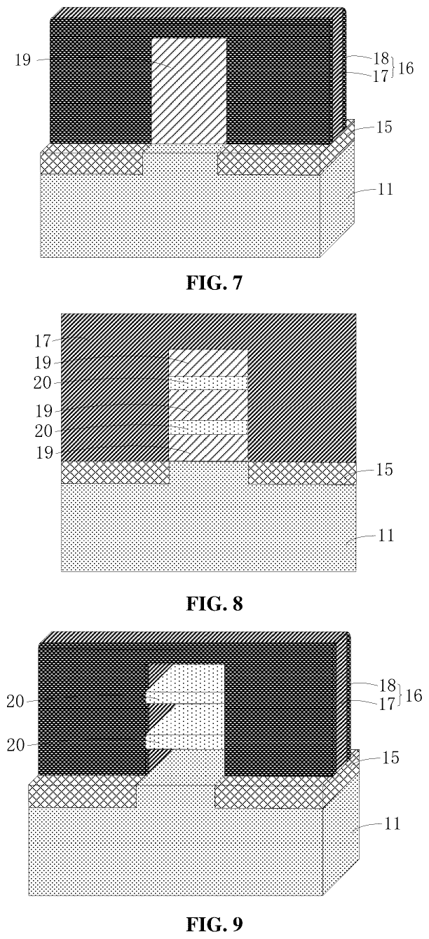

Reference is made to FIG. 7 to FIG. 9. Each remaining channel layer 14 is thinned along the thickness direction of the semiconductor substrate 11. After the thinning, the remaining channel layer 14 forms a corresponding first material layer 20.

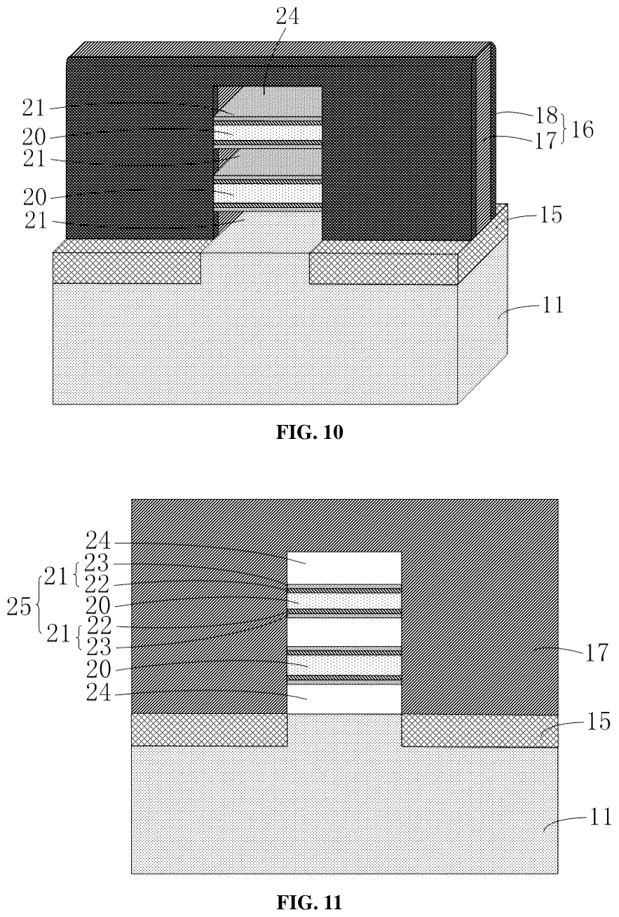

Reference is made to FIG. 7 and FIG. 8. Each remaining channel layers may be thinned through thermal oxidation, or through rapid thermal annealing under an oxygen-containing atmosphere, such that an oxide layer 19 is formed at two sides of each remaining channel layer along the thickness direction and two side of each remaining channel layer along the length direction. Reference is made to FIG. 9. The oxide layer(s) 19 are then removed though, for example, wet etching.

During the thermal oxidation or the rapid thermal annealing, each remaining channel layer of a partial thickness is oxidized and thus “consumed”, such that it is thinned. As a result, each remaining channel layer forms the corresponding first material layer after the thinning. A condition of the thermal oxidation or the rapid thermal annealing is not specifically limited herein.

A thickness by which each channel layer is thinned may depend on an initial thickness of such channel layer and a thickness of the corresponding second material layers that are to be formed in a subsequent step. In an embodiment, the thickness by which the channel layer is thinned is greater than or equal to the thickness of each corresponding second material layer. Thereby, the gate stack structure can be normally formed through filling in a subsequent step, and compatibility between a GAA transistor manufactured through the method provided herein and other GAA transistors manufactured through conventional methods can be improved.

Reference is made to FIG. 10 and FIG. 11. Second material layers 21 are formed at two sides of each first material layer 20 along a thickness direction of such first material layer 20 to obtain at least one nanostructure layer 25. Hence, each nanostructure layer 25 comprise the first material layer 20 and the second material layers 21 located at the two sides of the first material layer 20. At least a part of each second material layer 21 is different from the first material layer 20 in material.

Reference is further made to FIG. 9. In practice, the two sides along the length direction and the two sides along the thickness direction, of each first material layer 20, are exposed after the thinning. Afterwards, semiconductor material(s) may be formed through, for example, epitaxial growth, on a part of the semiconductor substrate 11, on the two sides of each first material layers 20 along the length direction, and on the two sides of each first material layer 20 along the thickness direction. Reference is further made to FIG. 10 and FIG. 11. The semiconductor material(s) may be patterned through, for example, dry etching, under masking of the mask layer 16, so that the semiconductor material(s) remain only on the two sides of each first material layer 20 along the thickness direction after the patterning. Thereby, the second material layers 21 are obtained. A material of the second material layer 21 may refer the foregoing description, and details would not be repeated herein.

Reference is further made to FIG. 10 and FIG. 11. After the nanostructure layer(s) 25 has been formed, there are gaps 24 in adjacency of each nanostructure layer 25, and each gap 24 is to be filled with a corresponding portion of the gate stack structure. In an embodiment, each gap 24 is located between the nanostructure layer(s) 25 and the semiconductor substrate 11, between the nanostructure layer(s) 25 and the mask layer 16, or between the adjacent nanostructure layers 25.

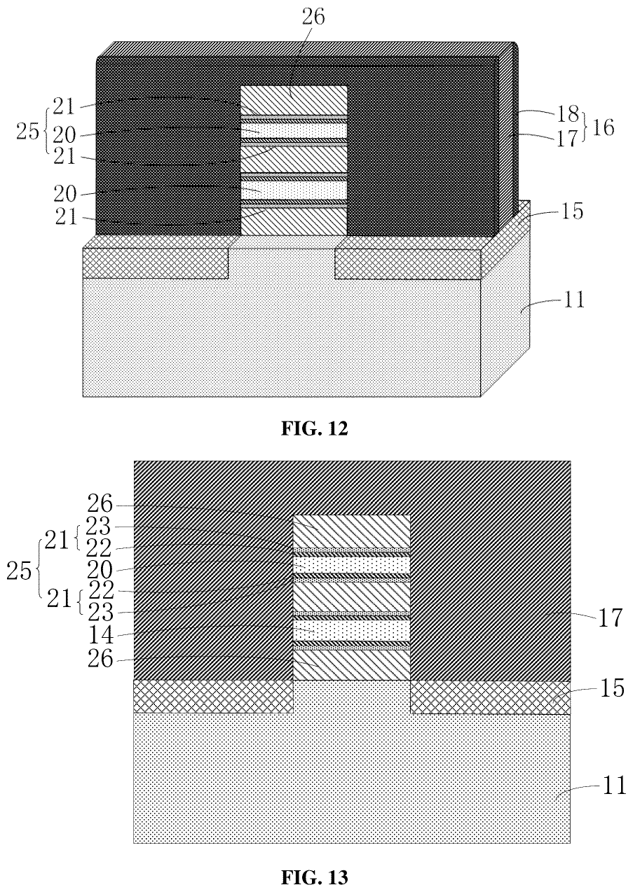

Reference is made to FIG. 12 to FIG. 14. The gaps 24 are then filled with a dielectric layer 26. The dielectric may be formed through, for example, deposition and etching.

The dielectric layer may comprise a single layer or multiple stacked layers. A material of the dielectric layer may stay the same or vary along the thickness direction of the semiconductor substrate. For example, the material of the dielectric layer may be at least one of: silicon oxide, silicon nitride, or silicon oxynitride.

In an embodiment, the GAA transistor comprises an inner sidewalls as illustrated in the foregoing description. In such case, after the dielectric layer has formed, the method further comprises a following step. Reference is made to FIG. 15. Edge portions of the dielectric layer 26 along a length direction (i.e., a direction point from the to-be-formed source to the to-be-formed drain, or vice versa) of the fin are removed through, for example, dry etching or a wet etching. Thereby, sidewalls of the remaining dielectric layer(s) 26 form recesses with respect to sidewalls of the first material layer(s) 20. Reference is made to FIG. 16. An inner sidewall 27 is formed at two sides of each remaining dielectric layer 26 along the length direction to fill the recesses through, for example, deposition and etching. A material of the inner sidewall 27 is different from that of the dielectric layer 26. The material of the inner sidewall 27 is capable to resistant an etchant for etching the dielectric layer 26 in a subsequent step. Thereby, a yield of the GAA transistors is improved.

In an embodiment, the material of the inner sidewall is an insulating material that is different from the material of the dielectric layer. The material of the inner sidewall may not be limited as long as is applicable to the method provided herein. For example, the material of the dielectric layer is silicon oxide, and the material of the inner sidewall is silicon nitride.

Reference is made to FIG. 17. A source 28 and a drain 29 may be then formed at two sides of the remaining fin along the length direction through, for example, epitaxial growth. The materials of the source 28 and the drain 29 may refer to the foregoing description.

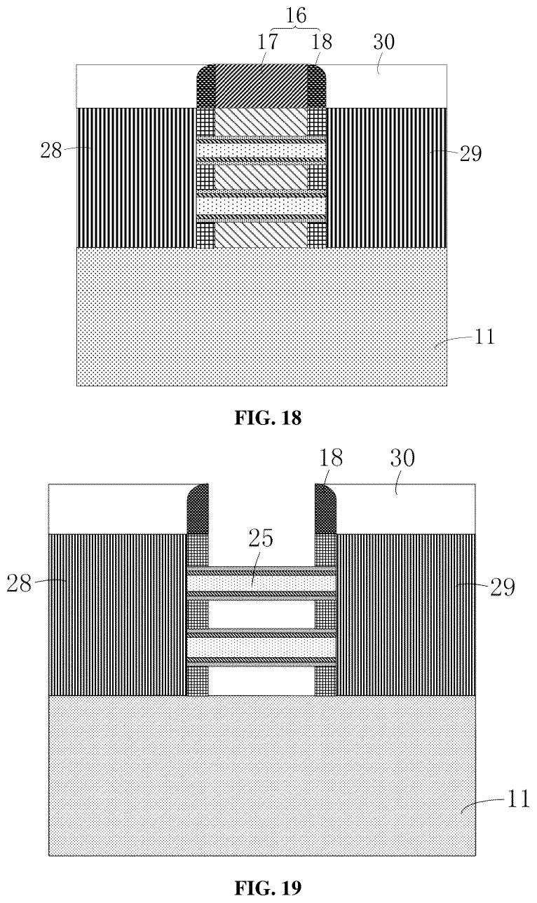

Reference is made to FIG. 18. An interlayer dielectric layer 30 may be formed to cover the semiconductor substrate 11. The interlayer dielectric layer 30 may be formed through, for example, deposition and chemical mechanical polishing. A top of the interlayer dielectric layer 30 is flush with a top of the mask layer 16. A material of the interlayer dielectric layer 30 may be an insulating material, such as silicon oxide, silicon nitride, or the like.

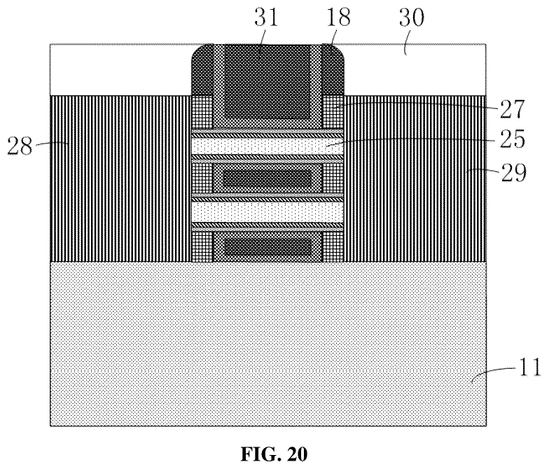

Reference is made to FIG. 19. At least a portion of the mask layer and at least a portion of the dielectric layer may be then removed through, for example, dry etching or wet etching.

In an embodiment, the mask layer comprises the sacrificial gate and the gate sidewall, and both the sacrificial gate and the dielectric layer need to be removed. In a case that the mask layer has a structure other than the sacrificial gate plus the gate sidewall, the mask layer may be completely removed.

In conventional technology, sacrificial layers made of a semiconductor material are removed to release nanostructure layers. Due to higher etching selectively can be achieved between the dielectric layer and the channel layer, the method provided herein is advantageous in releasing the nanostructure layers, especially when the material of the channel layer(s) comprises germanium silicon and the material of the sacrificial layer(s) comprises silicon. Thereby, a yield of the GAA transistor can be improved.

Reference is made to FIG. 20. A gate stack structure 31 surrounding each nanostructure layer 25 is then through, for example, atomic layer. A structure and a material of the gate stack structure 31 may refer to the foregoing description, and details would not be repeated herein.

Technical advantages and details of the method provided herein may refer to those of the GAA transistors in foregoing description and would not be repeated herein.

Some technical details of the foregoing processing, such as patterning and etching may be omitted in the description. Those skilled in the art have the knowledge of various technical means for forming a layer, a region, or the like having a required shape. In addition, those skilled in the art may derive other embodiments form the above embodiments. Although described separately in the foregoing description, the embodiments of the present disclosure may be combined combination to achieve a technical advantage.

Hereinabove the embodiments of the present disclosure have been described. The embodiments are only illustrative and are not intended for limiting the scope of the present disclosure. The scope of the disclosure is defined by the appended claims and their equivalents. Those skilled in the art may make various substitutions and modifications without departing from the scope of the present disclosure, and these substitutions and modifications shall fall within the scope of the present disclosure.

1. A gate-all-around transistor, comprising:
a semiconductor substrate;
a source, a drain, and at least one nanostructure layer, which are disposed on the semiconductor substrate; and
a gate stack structure surrounding each of the at least one nanostructure layer;
wherein the at least one nanostructure layer is disposed between the source and the drain;
wherein each of the at least one nanostructure layer comprises a first material layer and second material layers, and the second material layers are disposed at two sides of the first material layer along a thickness direction of the first material layer;
wherein each of the first material layer and the second material layers is in contact with both the source and the drain; and
wherein at least a part of the second material layers is different from the first material layer in material.

2. The gate-all-around transistor according to claim 1, further comprising:
a gate sidewall disposed at least at two sides of the gate stack structure along a length direction of the gate stack structure;
wherein the gate sidewall astride edge portions of the at least one nanostructure layer along the length direction.

3. The gate-all-around transistor according to claim 1, wherein the GAA transistor is a p-channel transistor.

4. The gate-all-around transistor according to claim 1, wherein a material of the first material layer comprises silicon.

5. The gate-all-around transistor according to claim 1, wherein each of the second material layers is identical in material throughout a thickness of the second material layer.

6. The gate-all-around transistor according to claim 1, wherein:
each of the second material layers comprises a first semiconductor layer and a second semiconductor layer,
the first semiconductor layer is disposed on the first material layer, and
the second semiconductor layer is disposed on the first semiconductor layer.

7. The gate-all-around transistor according to claim 6, wherein a material of the second semiconductor layer comprises silicon.

8. The gate-all-around transistor according to claim 6, wherein a thickness of the second semiconductor layer is greater than or equal to 0.3 nm and less than or equal to 1.5 nm.

9. The gate-all-around transistor according to claim 1, wherein:
a material of the second material layer comprises germanium silicon, and germanium content in the germanium silicon is greater than or equal to 10% and less than or equal to 60%.

10. The gate-all-around transistor according to claim 1, wherein a thickness of the first material layer is greater than or equal to 1 nm and less than or equal to 5 nm.

11. The gate-all-around transistor according to claim 1, further comprising:
an inner sidewall disposed between the gate stack structure and the source and between the gate stack structure and the drain.

12. A method for manufacturing a GAA transistor, comprising:
providing a semiconductor substrate;
providing a source, a drain, and at least one nanostructure layer, which are located on the semiconductor substrate, wherein:
the at least one nanostructure layer is disposed between the source and the drain;
each of the at least one nanostructure layer comprises a first material layer and second material layers, and the second material layers are disposed at two sides of the first material layer along a thickness direction of the first material layer;
each of the first material layer and the second material layers is in contact with both the source and the drain; and
at least a part of the second material layers is different from the first material layer in material;
providing a gate stack structure surrounding each of the at least one nanostructure layer.

13. The method according to claim 12, wherein providing the source, the drain, and the at least one nanostructure layer, which are located on the semiconductor substrate, comprises:
forming a fin on the semiconductor substrate, wherein the fin comprises at least one sacrificial layer and at least one channel layer that are alternately stacked along a thickness direction of the semiconductor substrate, and both a topmost layer and a bottommost layer among the at least one sacrificial layer and the at least one channel layer belong to the at least one sacrificial layer;
forming a mask layer astride the fin;
etching the fin under masking of the mask layer;
removing the at least one sacrificial layer remaining after the etching;
thinning, along the thickness direction of the semiconductor substrate, each of the at least one channel layer remaining after the etching to form the first material layer;
forming the second material layers at two sides of the first material layer along a thickness direction of the first material layer to obtain each of the at least one nanostructure layer;
filling one or more gaps with a dielectric layer, wherein each of the one or more gaps is located between adjacent ones of the at least one nanostructure layer, between and the semiconductor substrate and the at least one nanostructure layer, or between the at least one nanostructure layer and the mask layer; and
forming the source and the drain at two sides, respectively, of the fin remaining after the filling.

14. The method according to claim 13, wherein providing the gate stack structure surrounding each of the at least one nanostructure layer comprises:
removing at least a part of the mask layer and the dielectric layer; and
forming the gate stack structure surrounding each nanostructure layer.

15. The method according to claim 12, wherein the GAA transistor is a p-channel transistor, a material of the at least one channel layer comprises silicon, and a material of the at least one sacrificial layer comprises silicon germanium.

16. The method according to claim 13, wherein:
the mask layer comprises a sacrificial gate and a gate sidewall, and the gate sidewalls are disposed at least at two sides of the sacrificial gate along a direction pointing from the source to the drain; and
removing at least the part of the mask layer and the dielectric layer comprises removing the sacrificial gate and the dielectric layer.

17. The method according to claim 13, wherein thinning, along the thickness direction of the semiconductor substrate, each of the at least one channel layer remaining after the etching to form the first material layer comprises:
forming an oxide layer at two sides along the thickness direction and two sides along a direction pointing from the source to the drain, of each of the at least one channel layer remaining after the etching, through thermal oxidation, or through rapid thermal treatment under an oxygen-containing atmosphere; and
removing the oxide layer.

18. The method according to claim 13, wherein a material of the dielectric layer is identical throughout a thickness of the semiconductor substrate.

19. The method according to claim 13, wherein a thickness by which each of the at least one channel layer remaining after the etching is thinned is greater than or equal to a thickness of each of the second material layers.

20. The method according to claim 13, wherein after filling the one or more gaps with the dielectric layer and before forming the source and the drain at two sides, respectively, of the fin remaining after the filling, the method further comprises:
removing edge portions of the dielectric layer along a direction pointing from the source to the drain to form a recess with respect to a sidewall of the first material layer; and
filling the recess with an inner sidewall, wherein the inner sidewall is different from the dielectric layer in material.
